(19) United States
(12) Patent Application Publication
(10) Pub. No.: US 2025/0261530 A1
(43) Pub. Date: Aug. 14, 2025

(54) DISPLAY DEVICE

(71) Applicant: Samsung Display Co., LTD., Yongin-si (KR)

(72) Inventors: Eun Hye OH, Yongin-si (KR); Yong Myeong KIM, Yongin-si (KR); Byeong Gi KIM, Yongin-si (KR); Hye Rhee HAN, Yongin-si (KR)

(73) Assignee: Samsung Display Co., LTD., Yongin-si (KR)

(21) Appl. No.: 18/818,996

(22) Filed: Aug. 29, 2024

(30) Foreign Application Priority Data
Feb. 13, 2024 (KR) 10-2024-0020298

(51) Int. Cl. H10K 59/131; H10K 59/121; H10K 59/88

(52) U.S. Cl. CPC H10K 59/1315; H10K 59/1213; H10K 59/88

(57) ABSTRACT

A display device according to an embodiment may include a substrate, an active layer disposed on the substrate and including a first channel region, a first source region, and a first drain region, an insulating layer disposed on the active layer, and a gate conductive pattern disposed on the insulating layer, wherein the gate conductive pattern may include a first gate electrode overlapping the first channel region, the first gate electrode protruding from opposing sides of the active layer by more than about 4 μm in a width direction of the first channel region, the gate conductive pattern may also include an expanded pattern portion extending from the first gate electrode, the expanded pattern portion may be disposed in vicinity of the active layer.

### CROSS-REFERENCE TO RELATED APPLICATIONS

This application claims priority under 35 U.S.C. § 119 from Korea n Patent Application No. 10-2024-0020298 filed on Feb. 13, 2024 in the Korean Intellectual Property Office, the entire contents of which are incorporated herein by reference.

### BACKGROUND

### 1. Technical Field

Embodiments of the disclosure relate to a display device.

### 2. Description of the Related Art

As the information-oriented society evolves, various demands for display devices are ever increasing. Accordingly, a variety of types of display devices, including light-emitting display devices, are under development. A display device may include pixels including transistors.

### SUMMARY

Aspects of the disclosure provide a display device that can stabilize the characteristics of transistors.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device that may include an active layer disposed on a substrate and including a first channel region, a first source region, and a first drain region, an insulating layer disposed on the active layer, and a gate conductive pattern disposed on the insulating layer, wherein the gate conductive pattern may include a first gate electrode that overlapping a portion of the active layer corresponding to the first channel region, the first gate electrode protruding from opposing sides of the active layer by more than about 4 μm in a width direction of the first channel region, and an expanded pattern portion extending from the first gate electrode and disposed in vicinity of the active layer.

In an embodiment, the active layer may include an oxide semiconductor, and the gate conductive pattern may include a first metal layer containing titanium (Ti).

In an embodiment, the first metal layer may have a thickness of about 300 Å or more.

In an embodiment, the first metal layer may be disposed on (e.g., directly on) the insulating layer.

In an embodiment, the gate conductive pattern may further include a second metal layer disposed on the first metal layer and, the second metal layer may contain a metal having a lower resistance than titanium (Ti).

In an embodiment, the expanded pattern portion may include a first pattern disposed at a side of the first gate electrode in a first direction corresponding to the width direction of the first channel region, and the expanded pattern portion may extend in a second direction intersecting the first direction.

In an embodiment, the second direction may correspond to a length direction of the first channel region.

In an embodiment, the first pattern may be disposed in parallel to at least a portion of the active layer in a plan view.

In an embodiment, the expanded pattern portion may further include a second pattern disposed at an opposite side of the first gate electrode in the first direction.

In an embodiment, the second pattern may extend in the second direction.

In an embodiment, the active layer may further include a second channel region spaced apart from the first channel region, the second channel region overlapping a portion of the gate conductive pattern, and a second source region and a second drain region disposed at opposing sides of the second channel region, respectively.

In an embodiment, the gate conductive pattern may further include a second gate electrode overlapping the second channel region.

In an embodiment, the second gate electrode may protrude from opposing sides of the active layer by more than about 4 μm in a width direction of the second channel region.

In an embodiment, wherein the expanded pattern portion may further include a third pattern extending from the second gate electrode, wherein the third pattern may be spaced apart from the first pattern, and the second gate electrode may be disposed between the first pattern and the third pattern.

In an embodiment, the third pattern may be disposed in parallel to at least a portion of the active layer in a plan view.

In an embodiment, the active layer and the expanded pattern portion may not overlap each other in a plan view.

In an embodiment, the active layer and the expanded pattern portion may overlap each other in a plan view.

In an embodiment, the active layer may further include a dummy pattern portion, the dummy pattern portion may extend from the first source region or the first drain region, the dummy pattern portion may overlap the expanded pattern portion, and an end of the dummy pattern portion may be electrically floating.

In an embodiment, display device may further include a dummy pattern that may be disposed on the insulating layer and separated from the gate conductive pattern, and wherein the dummy pattern and the gate conductive pattern may comprise a same material.

In an embodiment, display device may further include a pixel including a transistor including the active layer and the first gate electrode.

According to embodiments of the disclosure, a display device may include a transistor including an active layer and a gate electrode. The gate electrode may protrude from both opposing sides of the active layer in the width direction of the active layer. According to embodiments of the disclosure, a display device may include a gate conductive pattern including an expanded pattern portion extending from the gate electrode. In some embodiments, the active layer may include an oxide semiconductor, and the gate conductive pattern may include a first metal layer containing a material having high hydrogen adsorption capacity, such as titanium (Ti).

According to embodiments of the disclosure, it may be possible to prevent hydrogen from being excessively introduced into the active layer. Accordingly, changes in the characteristics of the transistor can be prevented or reduced, and the characteristics of the transistor can become uniform and/or can be stabilized.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view of a display device according to an embodiment of the disclosure.

FIG. 2 is a plan view showing a display panel according to an embodiment of the disclosure.

FIG. 3 is a schematic diagram of an equivalent circuit of a pixel according to an embodiment of the disclosure.

FIG. 4 is a schematic cross-sectional view showing a display panel according to an embodiment of the disclosure.

FIG. 5 is a schematic cross-sectional view showing area Al of FIG. 4.

FIG. 6 is a plan view showing a first transistor according to an embodiment of the disclosure.

FIG. 7 is a graph showing changes in characteristics of the first transistor with respect to the length of a gate electrode and the thickness of a first metal layer.

FIGS. 8 to 14 are plan views showing first transistors according to embodiments of the disclosure.

FIGS. 15 to 17 are plan views showing first transistors according to embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in detail with reference to the accompanying drawings.

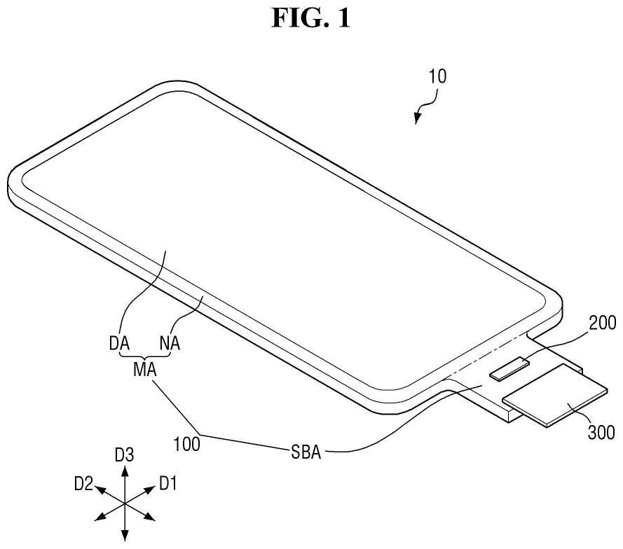

FIG. 1 is a perspective view showing a display device 10 according to an embodiment of the disclosure.

Referring to FIG. 1, a display device 10 is for displaying images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and an ultra mobile PC (UMPC), as well as the display screen of various products such as a television, a notebook, a monitor, a billboard and the Internet of Things.

According to the embodiment of the disclosure, the display device 10 may be a light-emitting display device including light-emitting elements. The display device 10 may be other types of display devices than a light-emitting display device. In the following description, an organic light-emitting display device may be employed as the display device 10. It is, however, to be understood that the type of the display device 10 according to the embodiments is not limited thereto.

In FIG. 1, a first direction D1, a second direction D2 and a third direction D3 are indicated. In an image display surface of the display device 10, the first direction D1 may be the lateral direction, the row direction or the horizontal direction of the display device 10, and the second direction D2 may intersect the first direction DR1 and, for example, may be the longitudinal direction, the column direction or the vertical direction of the display device 10. The third direction D3 may intersect the first direction D1 and the second direction D2 and may be the thickness direction or height direction of the display device 1, for example.

The display device 10 may include a display panel 100 including pixels and a first driver circuit (e.g., a panel-embedded gate driver circuit), etc. The display device 10 may further include a second driver circuit 200 electrically connected to the pixels and/or the first driver circuit, and a circuit board 300.

The display panel 100 may include a main area MA including a display area DA where images are displayed. According to the embodiment of the disclosure, the display panel 100 may further include a subsidiary area SBA located on a side of the main area MA. The shape of the display panel 100 may vary depending on embodiments. For example, the display panel 100 may not include the subsidiary area SBA.

The display panel 100 may be either rigid or flexible. For example, the display panel 100 may be entirely rigid, or may be flexible so that it can be curved, bent, folded, or rolled at least partially.

The main area MA may include a display area DA and a non-display area NA surrounding the display area DA. The non-display area NA may be located at the edges of the main area MA and may be in contact with the subsidiary area SBA.

According to the embodiment, the main area MA may have a generally rectangular shape that includes shorter sides in the first direction D1 and longer sides in the second direction D2. The corners where the shorter sides and the longer sides of the main area MA meet may be rounded or formed at the right angle. The shape of the main area MA may vary depending on embodiments. For example, the main area MA may include longer sides in the first direction D1 and shorter sides in the second direction D2.

In the display area DA, the pixels may be arranged and images may be displayed by the pixels. The display area DA may be located in the center of the main area MA and may occupy most of the main area MA.

According to the embodiment of the disclosure, the display area DA may have a shape that conforms to the shape of the main area MA. For example, the display area DA may have a generally rectangular shape that includes shorter sides in the first direction D1 and longer sides in the second direction D2. The corners where the shorter sides and the longer sides of the display area DA meet may be rounded or formed at the right angle. The shape of the display area DA may vary depending on embodiments.

The non-display area NA may be located immediately around the display area DA. For example, the non-display area NA may be located at the edges of the main area MA to surround the display area DA. In case that the display panel 100 includes the subsidiary area SBA, the non-display area NA may be in contact with the subsidiary area SBA.

Lines (or portions of the lines) electrically connected to the pixels may be disposed in the non-display area NA. According to the embodiment of the disclosure, the first driver circuit that supplies first driving signals to the pixels PX may be further disposed in the non-display area NA.

According to the embodiment of the disclosure, the first driver circuit may be a gate driver circuit that supplies respective gate signals (e.g., scan signals and/or emission control signals) to the pixels PX. For example, the first driver circuit may include stage circuits for generating scan signals and/or stage circuits for generating emission control signals of the pixels PX

The subsidiary area SBA may be located on a side of the main area MA. For example, the subsidiary area SBA may protrude from a side of the main area MA in the first direction D1. For example, the subsidiary area SBA may protrude from the lower end of the main area MA in the first direction D1.

According to the embodiment, the subsidiary area SBA may have a smaller width than the main area MA. For example, the subsidiary area SBA may have a smaller width than the main area MA in the first direction D1.

Lines (or portions of the lines) and pads may be provided in the subsidiary area SBA. For example, in the subsidiary area SBA, the lines and the pads may be disposed, which may be electrically connected to the pixels and/or the first driver circuit located in the main area MA, the second driver circuit 200 may be located in the subsidiary area SBA, and/or the circuit board 300. In the following description of the embodiments, the term “connection” may encompass electrical connection and/or physical connection.

According to the embodiment, the second driver circuit 200 may be mounted in the subsidiary area SBA. The circuit board 300 may be disposed on a portion of the subsidiary area SBA.

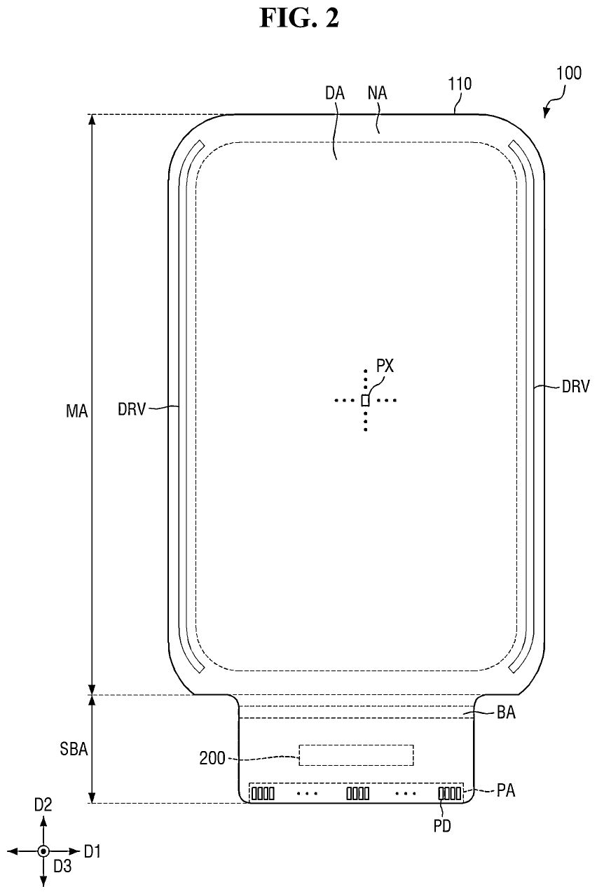

According to the embodiment of the disclosure, the subsidiary area SBA of the display panel 100 may be flexible so that it can be curved, bent, folded, or rolled at least partially. According to the embodiment of the disclosure, a portion of the subsidiary area SBA that may be adjacent to the main area MA (e.g., the bending area BA of FIG. 2) may be bent. Then, a portion of the subsidiary area SBA in which the second driver circuit 200 and the like may be mounted may be located below the main area MA.

The second driver circuit 200 may be electrically connected to the pixels PX of the display area DA. The second driver circuit 200 may include a data driver circuit for driving the pixels. The second driver circuit 200 may supply the respective data signals to the pixels PX

According to the embodiment, the second driver circuit 200 may be prepared as an integrated circuit (IC) chip and mounted in the subsidiary area SBA. According to an embodiment, the second driver circuit 200 may be disposed or mounted on the circuit board 300 in the subsidiary area SBA, or may be disposed or mounted on another circuit board electrically connected to the display panel 100 through the circuit board 300.

The circuit board 300 may be disposed on a portion of the subsidiary area SBA. For example, the circuit board 300 may be bonded on the pads located at a location (e.g., the lower edge) of the subsidiary area SBA, and may supply or transmit supply voltages and driving signals for driving the display panel 100 and/or the second driver circuit 200 to the display panel 100. For example, the circuit board 300 may supply the display panel 100 with input video data (e.g., digital video data), driving signals (e.g., timing signals) for driving the first driver circuit and/or the second driver circuit 200 and supply voltages for driving the pixels, the first driver circuit and/or the second driver circuit 200. The circuit board 300 may be, but is not limited to, a flexible printed circuit board (FPCB), a printed circuit board (PCB) or a flexible film such as chip on film (COF). In case that the display panel 100 does not include the subsidiary area SBA, the pads may be disposed on a portion of the main area MA, and the circuit board 300 may be bonded onto the pads.

FIG. 2 is a plan view showing the display panel 100 according to the embodiment of the disclosure. FIG. 2 shows the display panel 100 in case that it is not bent but is unfolded.

Referring to FIGS. 1 and 2, the display panel 100 may include the main area MA including the display area DA and the non-display area NA, and the subsidiary area SBA including a pad area PA. According to the embodiment of the disclosure, the subsidiary area SBA may further include a driver circuit mounting area where the second driver circuit 200 may be mounted.

According to the embodiment of the disclosure, the subsidiary area SBA may further include a bending area BA. According to the embodiment of the disclosure, the bending area BA may be adjacent to the main area MA. The display panel 100 may be bent in the bending area BA, and accordingly, a portion of the subsidiary area SBA may be located under the main area MA.

The display panel 100 may include a substrate 110 (or base layer) forming a bottom surface. The substrate 110 may include the main area MA including the display area DA and the non-display area NA. According to the embodiment of the disclosure, the substrate 110 may further include the subsidiary area SBA protruding from the main area MA.

The display panel 100 may include pixels PX and pads PD disposed on the substrate 110. According to the embodiment of the disclosure, the display panel 100 may further include a first driving circuit DRV and lines disposed on the substrate 110. The lines may be electrically connected to the pixels PX, the first driver circuit DRV, the second driver circuit 200, and the pads PD.

The pixels PX may be arranged in the display area DA. Lines (or portions of the lines) electrically connected to the pixels PX may be further disposed in the display area DA. For example, scan lines, data lines and pixel power lines electrically connected to the pixels PX may be further disposed in the display area DA. In the display device 10 in which the emission timing of the pixels PX may be controlled by an emission control signal, emission control lines for transmitting the emission control signal to each of the pixels PX may be further disposed in the display area DA.

The first driver circuit DRV may be disposed in the non-display area NA. The first driver circuit DRV may be electrically connected to multiple pads PD provided in the pad area PA. The first driver circuit DRV may receive gate control signals (e.g., gate start pulse and gate clock signals) required to generate gate signals from the pads PD and gate supply voltages (e.g., gate-high voltage and gate-low voltage). The first driver circuit DRV may be electrically connected to the pixels PX through the gate lines (e.g., scan lines and/or emission control lines), and may supply the gate signals (e.g., scan signals and/or emission control signals) to the pixels PX.

The first driver circuit DRV may be located on at least one side of the display area DA. As an example, the first driver circuit DRV may be located only on a side (e.g., left or right side) of the display area DA, or may be located on both sides (e.g., left and right sides) of the display area DA.

According to the embodiment of the disclosure, the first driver circuit DRV may be a built-in circuit formed in the display panel 100 together with the pixels PX. For example, the first driver circuit DRV may be formed in the display panel 100 using the gate-in panel technology.

The pads PD may be disposed in the pad area PA. The pads PD may electrically connect the display panel 100 and/or the second driver circuit 200 with the circuit board 300, etc. The pads PD may include signal pads and power pads for transmitting the driving signals and the supply voltages required for driving the pixels PX, the first driver circuit DRV and/or the second driver circuit 200 to the inside of the display panel 100. The circuit board 300 may be disposed on the pad area PA.

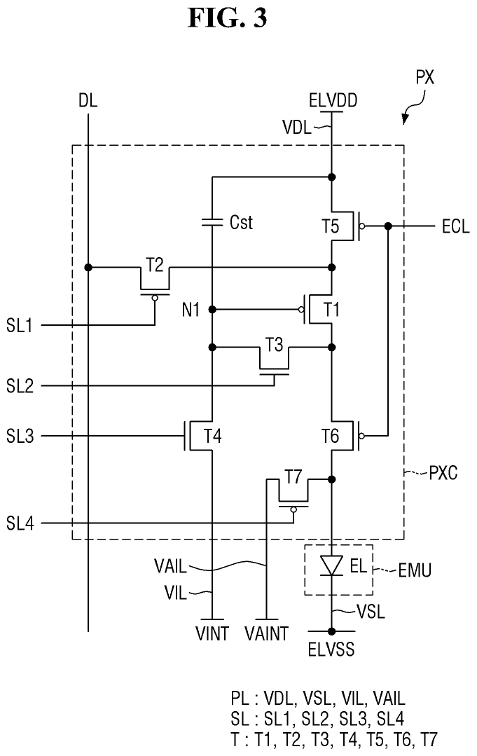

FIG. 3 is a schematic diagram of an equivalent circuit of a pixel PX according to an embodiment of the disclosure. For example, FIG. 3 shows one of the pixels PX that may be disposed in the display area DA of FIGS. 1 and 2.

Referring to FIG. 3, the pixel PX may include an emission unit EMU including at least one light-emitting element EL, and a pixel circuit PXC (also referred to as a “pixel driver”) electrically connected to the emission unit EMU. The pixel PX may be electrically connected to at least one scan line SL, a data line DL, and pixel power lines PL. For example, the pixel PX may be electrically connected to a first scan line SL1, a second scan line SL2, a third scan line SL3, a fourth scan line SL4, a data line DL, a first pixel voltage line VDL, a second pixel voltage line VSL, a first initialization voltage line VIL, and a second initialization voltage line VAIL. According to the embodiment of the disclosure, the pixel PX may be further electrically connected to the emission control line ECL. The configuration of the pixel PX and the lines electrically connected to the pixel PX may vary depending on embodiments.

The light-emitting element EL may be electrically connected between the second pixel voltage line VSL applying the second pixel supply voltage ELVSS and the pixel circuit PXC. According to the embodiment of the disclosure, the second pixel supply voltage ELVSS may be a low-level pixel driving voltage. The light-emitting element EL may be the light source of the pixel PX and may emit light in response to a driving current supplied from the pixel circuit PXC.

The light-emitting element EL may be, but is not limited to, an organic light-emitting diode. For example, the light-emitting element EL may be an inorganic light-emitting element, a quantum-dot light-emitting element, or other types of light-emitting element.

The pixel circuit PXC may control the emission timing and luminance of the light-emitting element EL by controlling the driving current supplied to the light-emitting element EL. The pixel circuit PXC may include at least one pixel transistor T and a capacitor Cst. According to the embodiment of the disclosure, the pixel circuit PXC may include first to seventh pixel transistors T1 to T7.

The first pixel transistor T1 may include a gate electrode electrically connected to a first node N1, a first electrode electrically connected to the first pixel voltage line VDL via the fifth pixel transistor T5 and a second electrode electrically connected to the emission unit EMU via the sixth pixel transistor T6. One of the first electrode and the second electrode may be a source electrode, and another may be a drain electrode. For example, the first electrode may be the source electrode, the second electrode may be the drain electrode. The first pixel transistor T1 may control a source-drain current (hereinafter referred to as a driving current) flowing between the first electrode and the second electrode in response to the voltage applied to the gate electrode (e.g., the voltage of the first node N1 corresponding to the voltage of the data signal). For example, the first pixel transistor T1 may be a driving transistor of the pixel PX.

The second transistor T2 may include a gate electrode electrically connected to a first scan line SL1, a first electrode electrically connected to a data line DL, and a second electrode electrically connected to the first electrode of the first pixel transistor T1. The second transistor T2 may be turned on by a first scan signal supplied to the first scan line SL1 to electrically connect the first electrode of the first pixel transistor T1 with the data line DL. In case that the second pixel transistor T2 is turned on, the voltage of the data signal supplied to the data line DL may be applied to the first electrode of the first pixel transistor T1.

The third transistor T3 may include a gate electrode electrically connected to a second scan line SL2, a first electrode electrically connected to the second electrode of the first pixel transistor T1, and a second electrode electrically connected to the first node N1. The third pixel transistor T3 may be turned on by a second scan signal supplied to the second scan line SL2 to electrically connect the gate electrode of the first pixel transistor T1 with the second electrode. In case that the third pixel transistor T3 is turned on, the first pixel transistor T1 may behave as a diode.

The fourth transistor T4 may include a gate electrode electrically connected to the third scan line SL3, a first electrode electrically connected to the first node N1, and a second electrode electrically connected to the first initialization voltage line VIL. The fourth pixel transistor T4 may be turned on by a third scan signal supplied to the third scan line SL3 to electrically connect the first node N1 with the first initialization voltage line VIL. In case that the fourth pixel transistor T4 is turned on, the first initialization voltage VINT (e.g., gate initialization voltage) of the first initialization voltage line VIL may be applied to the gate electrode of the first pixel transistor T1.

The fifth pixel transistor T5 may include a gate electrode electrically connected to the emission control line ECL, a first electrode electrically connected to the first pixel voltage line VDL, and a second electrode electrically connected to the first electrode of the first pixel transistor T1. The fifth pixel transistor T5 may be turned on by an emission control signal supplied on the emission control line ECL, to electrically connect the first electrode of the first pixel transistor T1 with the first pixel voltage line VDL from which the first pixel supply voltage ELVDD may be applied. In case that the fifth pixel transistor T5 is turned on, the first pixel supply voltage ELVDD may be applied to the first electrode of the first pixel transistor T1. According to the embodiment of the disclosure, the first pixel supply voltage ELVDD may be a high-level pixel driving voltage.

The sixth pixel transistor T6 may include a gate electrode electrically connected to the emission control line ECL, a first electrode electrically connected to the second electrode of the first pixel transistor T1, and a second electrode electrically connected to the light-emitting clement EL. The sixth pixel transistor T6 may be turned on by the emission control signal supplied on the emission control line ECL to electrically connect the first pixel transistor T1 with the light-emitting element EL. In case that both the fifth and sixth pixel transistors T5 and T6 are turned on, a driving current of a magnitude proportional to the voltage of the first node N1 may flow through the light-emitting element EL.

The seventh pixel transistor T7 may include a gate electrode electrically connected to the fourth scan line SL4, a first electrode electrically connected to the anode electrode of the light-emitting element EL, and a second electrode electrically connected to the second initialization voltage line VAIL. The second pixel transistor T7 may be turned on by a fourth scan signal supplied to the fourth scan line SL4 to electrically connect the anode electrode of the light-emitting element EL with the second initialization voltage line VAIL. The fourth scan signal may be either identical to or different from the first scan signal. In case that the seventh pixel transistor T7 is turned on, a second initialization voltage VAINT (e.g., an anode initialization voltage) of the second initialization voltage line VAIL may be applied to the anode electrode of the light-emitting element EL.

The capacitor Cst may be electrically connected between the first pixel voltage line VDL and the first node N1. The capacitor Cst may be charged with a voltage equal to the voltage of the data signal applied to the first node N1.

An active layer (e.g., a semiconductor pattern including the respective channel region) of each of the pixel transistors T (e.g., the first to seventh pixel transistors T1 to T7) may include polysilicon, amorphous silicon, oxide semiconductor, or other semiconductor materials. According to embodiments, at least one pixel transistor T may include an active layer containing an oxide semiconductor.

According to an embodiment of the disclosure, some of the pixel transistors T may include a different type of semiconductor material from the others. Some of the pixel transistors T may be formed as transistors of different conductivity types from others. For example, the first, second, fifth, sixth and seventh pixel transistors T1, T2, T5, T6 and T7 may be formed as p-type polysilicon transistors including active layers formed of polysilicon. The third and fourth pixel transistors T3 and T4 may be formed as n-type oxide transistors including active layers formed of an oxide semiconductor. As the first, second, fifth, sixth and seventh pixel transistors T1, T2, T5, T6 and T7 may be formed as polysilicon transistors resistant to bias stress, the on-current or operating characteristics of the transistors can be properly ensured. As the third and fourth pixel transistors T3 and T4 may be formed as oxide transistors with low off-current, it may be possible to prevent or improve leakage current of the pixel PX through the third and fourth pixel transistors T3 and T4, etc. As a result, the pixel PX can be stably driven and luminance deviation of the pixels PX can be prevented or reduced.

According to an embodiment of the disclosure, active layers formed of different materials may be disposed in different layers in the display panel 100. For example, the active layers formed of polysilicon and the active layers formed of an oxide semiconductor may be disposed in different layers on the substrate 110 of the display panel 100.

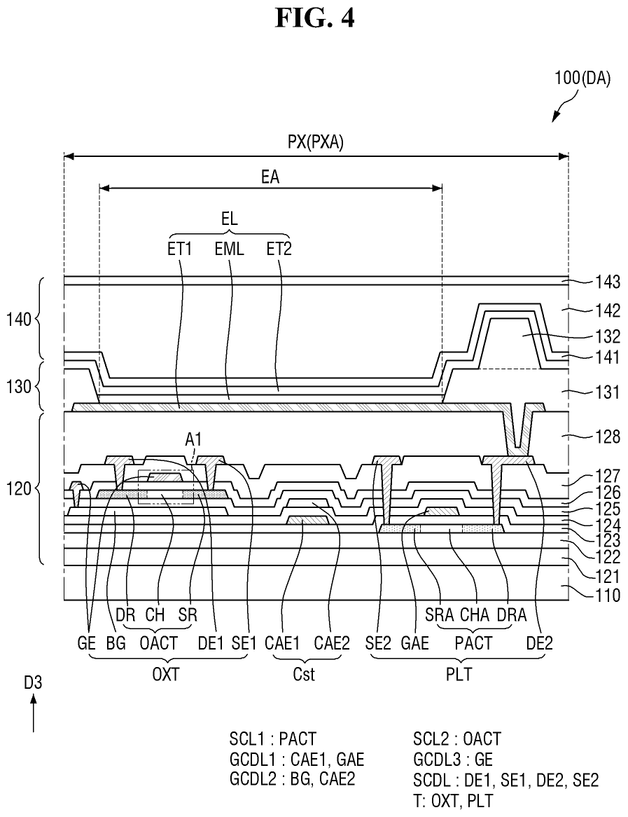

FIG. 4 is a schematic cross-sectional view showing the display panel 100 according to the embodiment of the disclosure. For example, FIG. 4 schematically shows a cross section of a portion of the display area DA corresponding to a pixel area PXA where a pixel PX may be located.

FIG. 4 shows a light-emitting display panel including a light-emitting clement EL (e.g., an organic light-emitting diode) as an example of the display panel 100 to which the embodiments can be applied. It should be understood, however, that the structure and type of the display panel 100 and the display device 10 including the same according to the embodiments are not limited thereto. For example, the display device 10 may be a light-emitting display device such as an organic light-emitting display device including organic light-emitting diodes, a quantum-dot light-emitting display device including quantum-dot light-emitting layer, and an ultra-small light-emitting display device using ultra-small light-emitting diodes such as micro or nano light-emitting diodes (micro LEDs or nano LEDs). The display device 10 may be other types of display devices than a light-emitting display device.

Referring to FIG. 4 in conjunction with FIGS. 1 to 3, the display panel 100 may include the substrate 110, and a circuit layer 120, an emission material layer 130 and an encapsulation layer 140 disposed on the substrate 110. According to the embodiment of the disclosure, the circuit layer 120, the emission material layer 130 and the encapsulation layer 140 may be sequentially disposed on the substrate 110 in the third direction D3. Although the circuit layer 120 and the emission material layer 130 may be separated from each other according to the embodiments, embodiments of the disclosure are not limited thereto. For example, the circuit layer 120 and the emission material layer 130 may be integrated.

The substrate 110 may be a base member for forming the display panel 100 and may include the display area DA where the pixels PX are arranged. According to the embodiment of the disclosure, the substrate 110 may be either a flexible substrate that can be bent, folded or rolled, or a rigid substrate that may not be substantially deformed. The substrate 110 may include an insulating material such as glass and polymer resin, or other materials.

The circuit layer 120 may include pixel circuits PXC and lines provided to the pixels PX. For example, the circuit layer 120 may include circuit elements that form the pixel circuit PXC of each of the pixels PX (e.g., the pixel transistors T and the capacitor Cst of FIG. 3) and the lines electrically connected to the pixels PX (e.g., the pixel power lines PL, the scan lines SL, the emission control lines ECL, and the data lines DL). According to an embodiment of the disclosure, the circuit layer 120 may further include circuit elements forming the first driver circuit DRV and lines electrically connected to the first driver circuit DRV. According to an embodiment of the disclosure, the circuit layer 120 may be formed entirely on a surface of the substrate 110.

FIG. 4 shows a first transistor OXT, a second transistor PLT and a capacitor Cst provided in the pixel area PXA of each pixel PX among the elements that may be provided in the circuit layer 120. In the display panel 100 shown in FIG. 4, the first transistor OXT and the second transistor PLT may include active layers containing different materials, and the active layers of the first transistor OXT and the second transistor PLT may be disposed in different layers in the circuit layer 120. It should be understood, however, that the embodiments of the disclosure are not limited thereto. For example, the active layers of the pixel transistors T provided in each of the pixels PX may be formed simultaneously using a same material (e.g., an oxide semiconductor).

At least some of the pixel transistors T may be oxide transistors including an oxide semiconductor. For example, the first transistor OXT may be an oxide transistor, and an active layer OACT of the first transistor OXT may include an oxide semiconductor. For example, the first transistor OXT may represent first type of transistors (e.g., n-type oxide transistors) including a first semiconductor material (e.g., an oxide semiconductor) among the pixel transistors T forming each pixel circuit PXC. For example, the first transistor OXT may be one of the third and fourth pixel transistors T3 and T4 of FIG. 3.

The second transistor PLT may be a transistor formed using a different semiconductor material from the first transistor OXT. For example, the second transistor PLT may be a poly-silicon transistor, and the active layer PACT of the second transistor PLT may include polysilicon. For example, the second transistor PLT may represent second type of transistors (e.g., p-type polysilicon transistors) including a second semiconductor material (e.g., polysilicon) among the pixel transistors T. As an example, the second transistor PLT may be one of the first, second, fifth, sixth and seventh pixel transistors T1, T2, T5, T6 and T7 of FIG. 3. In FIG. 4, as the second transistor PLT, a transistor (e.g., the sixth pixel transistor T6 of FIG. 3) electrically connected to the light-emitting element EL among the second type transistors may be shown.

The cross-section of the pixels PX may vary depending on the type and/or structure of each pixel PX and the display panel 100 including it. For example, the positions and formation order of the first transistor OXT, the second transistor PLT, and the capacitor Cst may vary depending on embodiments. According to the embodiment where the pixel transistors T may be formed using the same semiconductor material (e.g., an oxide semiconductor), the display panel 100 may include only one semiconductor layer (e.g., an oxide semiconductor layer).

The circuit layer 120 may include at least one semiconductor layer and multiple conductive layers for forming circuit elements and lines. According to an embodiment where the pixel transistors T include the first transistor OXT and the second transistor PLT including different semiconductor materials, the circuit layer 120 may include multiple semiconductor layers (e.g., an oxide semiconductor layer and a polysilicon semiconductor layer). The circuit layer 120 may further include multiple insulating layers disposed between the semiconductor layers and the conductive layers.

According to the embodiment of the disclosure, the circuit layer 120 may include a first semiconductor layer SCL1 (e.g., a polysilicon semiconductor layer), a first insulating layer 123 (e.g., a first gate insulator), a first gate conductive layer GCDL1 (or a first conductive layer), a second insulating layer 124 (e.g., a second gate insulator), a second gate conductive layer GCDL2 (or a second conductive layer), a third insulating layer 125 (e.g., a first interlayer dielectric layer), a second semiconductor layer SCL2 (e.g., an oxide semiconductor layer), a fourth insulating layer 126 (e.g., a third gate insulator), a third gate conductive layer GCDL3 (or a third conductive layer), a fifth insulating layer 127 (e.g., a second interlayer dielectric layer), a source-drain conductive layer SCDL (or a fourth conductive layer), and a sixth insulating layer 128 (e.g., a via layer or a planarization layer), which may be sequentially disposed on the substrate 110 in the third direction D3.

According to the embodiment, the circuit layer 120 may further include at least one insulating layer and/or at least one conductive layer disposed between the substrate 110 and the first semiconductor layer SCL1. For example, the circuit layer 120 may further include at least one of a barrier layer 121 and a buffer layer 122 disposed between the substrate 110 and the first semiconductor layer SCL1. According to an embodiment of the disclosure, the circuit layer 120 may further include a lower conductive layer (not shown) disposed between the barrier layer 121 and the buffer layer 122 and including at least one line and/or conductive light-blocking layer.

According to an embodiment of the disclosure, the circuit layer 120 may further include at least one conductive layer (e.g., a bridge electrode connecting the light-emitting element EL with the second transistor PLT and/or a fifth conductive layer in which at least one line may be disposed) disposed on the sixth insulating layer 128, and at least one insulating layer (e.g., a planarization layer covering the patterns of the fifth conductive layer).

According to an embodiment of the disclosure, the circuit layer 120 may not include the first semiconductor layer SCL1, etc. For example, in case that all of the pixel transistors T are formed as the same oxide transistors as the first transistor OXT and the gate electrodes of the pixel transistors T are disposed in a same layer, the circuit layer 120 may not include the first semiconductor layer SCL1, the first insulating layer 123, the first gate conductive layer GCDL1 (or first conductive layer), or the second insulating layer 124 (e.g., the second gate insulator). In this instance, the first capacitor electrode CAE may be disposed in another conductive layer (e.g., the third gate conductive layer GCDL3).

The barrier layer 121 and the buffer layer 122 may be disposed on the substrate 110. As an example, the barrier layer 121 and the buffer layer 122 may be sequentially disposed on the substrate 110.

The barrier layer 121 and the buffer layer 122 can protect elements disposed in the circuit layer 120 and the emission material layer 130 from moisture that permeates through the substrate 110, which may be vulnerable to moisture permeation. The barrier layer 121 and the buffer layer 122 may include at least one inorganic film including an inorganic insulating material (e.g., silicon nitride, silicon oxide, silicon oxynitride, titanium oxide, aluminum oxide, other inorganic insulating materials, or a combination thereof). The materials of the barrier layer 121 and the buffer layer 122 may vary depending on embodiments.

The first transistor OXT, the second transistor PLT and the capacitor Cst may be disposed on the buffer layer 122 (or the substrate 110).

The first transistor OXT may include an active layer OACT and a gate electrode GE. The gate electrode GE may be disposed on the active layer OACT to overlap a part (e.g., a channel region) of the active layer OACT. At least one insulating layer (e.g., the fourth insulating layer 126) may be disposed between the active layer OACT and the gate electrode GE.

According to the embodiment of the disclosure, the active layer OACT may be provided in the second semiconductor layer SCL2 disposed on the third insulating layer 125. The second semiconductor layer SCL2 may include the active layers OACT of the first transistor OXT and the oxide transistors provided in the display panel 100 (e.g., the third and fourth pixel transistors T3 and T4 in FIG. 3). The active layers OACT of the second semiconductor layer SCL2 may be covered by the fourth insulating layer 126.

The active layer OACT may include an oxide semiconductor. For example, the active layer OACT may include an oxide semiconductor including at least one of indium (In), gallium (Ga), zinc (Zn), tin (Sn) and hafnium (Hf), or other oxide semiconductor. For example, the active layer OACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), other oxide semiconductors, or a combination thereof. The active layers OACT of the second semiconductor layer SCL2 may include the same oxide semiconductor.

The active layer OACT may include a channel region CH overlapping the gate electrode GE, and a source region SR and a drain region DR located on both (or opposing) sides of the channel region CH. According to an embodiment of the disclosure, the source region SR and the drain region DR of the active layer OACT may be electrically connected to a source electrode SE1 and a drain electrode DE1, respectively. According to an embodiment of the disclosure, the source region SR and/or the drain region DR of the active layer OACT may be the source electrode and/or the drain electrode of the first transistor OXT.

According to the embodiment of the disclosure, the gate electrode GE may be provided in the third gate conductive layer GCDL3 disposed on the fourth insulating layer 126. The third gate conductive layer GCDL3 may include gate electrodes GE of oxide transistors including the first transistor OXT. The patterns of the third gate conductive layer GCDL3 including the gate electrodes GE (e.g., electrodes, conductive patterns and/or at least one line provided in the third gate conductive layer GCDL3) may be covered by the fifth insulating layer 127.

The gate electrodes GE may include at least one conductive material (e.g., at least one of molybdenum (Mo), titanium (Ti), aluminum (Al), chromium (Cr), gold (Au), nickel (Ni), neodymium (Nd), copper (Cu), other metals, an alloy thereof, or other conductive materials), and may be formed in a single-layer or multi-layer pattern. The patterns of the third gate conductive layer GCDL3 may include the same conductive material and may have the same cross-sectional structure. According to an embodiment of the disclosure, the patterns of the third gate conductive layer GCDL3 may include titanium (Ti).

According to the embodiment of the disclosure, the first transistor OXT may further include a bottom gate electrode BG (or light-blocking layer) disposed under the active layer OACT. According to the embodiment of the disclosure, the bottom gate electrode BG may be electrically connected to the gate electrode GE and may be used as a back-gate electrode to adjust the characteristics of the first transistor OXT. According to an embodiment, the bottom gate electrode BG may not be electrically connected to the gate electrode GE, or the first transistor OXT may not include the bottom gate electrode BG.

According to the embodiment of the disclosure, the bottom gate electrode BE may be provided in the second gate conductive layer GCDL2 disposed on the second insulating layer 124. The second gate conductive layer GCDL2 may include the bottom gate electrodes BG of at least some of the oxide transistors including the first transistor OXT. According to the embodiment of the disclosure, the second gate conductive layer GCDL2 may further include a second capacitor electrode CAE2 forming the capacitor Cst of each pixel PX. The patterns of the second gate conductive layer GCDL2 including the bottom gate electrodes BG (e.g., electrodes, conductive patterns and/or at least one line provided in the second gate conductive layer GCDL2) may be covered by the third insulating layer 125.

The bottom gate electrode BG may include at least one conductive material and may be formed in a single-layer or multi-layer pattern. The patterns of the second gate conductive layer GCDL2 may include a same conductive material and may have a same cross-sectional structure.

According to the embodiment of the disclosure, the first transistor OXT may further include a source electrode SE1 and a drain electrode DE1 electrically connected to different regions of the active layer OACT. For example, the first transistor OXT may include the source electrode SE1 electrically connected to the source region SR of the active layer OACT and the drain electrode DE1 electrically connected to the drain region DR of the active layer OACT. According to an embodiment, the first transistor OXT may include no separate source electrode SE1 and/or drain electrode DE1, and the source region SR and/or the drain region DR of the active layer OACT may work as the source electrode and/or the drain electrode of the first transistor OXT.

According to the embodiment of the disclosure, the source electrode SE1 and the drain electrode DE1 may be provided in the source-drain conductive layer SCDL disposed on the fifth insulating layer 127. The source-drain conductive layer SCDL may include the source electrodes SE1 and SE2 and/or the drain electrodes DE1 and DE2 of at least some of the pixel transistors T. The patterns of the source-drain conductive layer SCDL (e.g., electrodes, conductive patterns, and/or at least one line disposed in the source-drain conductive layer SCDL) may be covered by the sixth insulating layer 128.

The source electrodes SE1 and SE2 and the drain electrodes DE1 and DE2 may include at least one conductive material and may be formed in a single-layer or multi-layer pattern. The patterns of the source-drain conductive layer SCDL may include a same conductive material and have a same cross-sectional structure.

The second transistor PLT may include an active layer PACT and a gate electrode GAE. The gate electrode GAE may be disposed on the active layer PACT such that it overlaps a portion (e.g., a channel area CHA) of the active layer PACT. At least one insulating layer (e.g., the first insulating layer 123) may be disposed between the active layer PACT and the gate electrode GAE.

According to the embodiment of the disclosure, the active layer PACT may be provided in the first semiconductor layer SCL1 disposed on the buffer layer 122. The first semiconductor layer SCL1 may include the active layers PACT of the polysilicon transistors provided in the display panel 100, including the second transistor PLT (e.g., the first, second, fifth, sixth and seventh pixel transistors T1, T2, T5, T6 and T7 of FIG. 3). The active layers PACT of the first semiconductor layer SCL1 may be covered by the first insulating layer 123.

The active layer PACT of the second transistor PLT may include a semiconductor material different from the active layer OACT of the first transistor OXT. For example, the active layer PACT may include crystallized polysilicon. The active layers PACT of the first semiconductor layer SCL1 may include a same semiconductor material.

The active layer PACT may include a channel region CHA overlapping the gate electrode GAE, and a source region SRA and a drain region DRA located on both sides of the channel region CHA. According to an embodiment of the disclosure, the source region SRA and the drain region DRA of the active layer PACT may be electrically connected to a source electrode SE2 and a drain electrode DE2, respectively. According to an embodiment of the disclosure, the source region SRA and/or the drain region DRA of the active layer PACT may be the source electrode and/or the drain electrode of the second transistor PLT.

According to the embodiment of the disclosure, the gate electrode GAE may be provided in the first gate conductive layer GCDL1 disposed on the first insulating layer 123. The first gate conductive layer GCDL1 may include gate electrodes GAE of polysilicon transistors, including the second transistor PLT. According to the embodiment of the disclosure, the first gate conductive layer GCDL1 may further include a first capacitor electrode CAE1 forming the capacitor Cst of each pixel PX. The patterns of the first gate conductive layer GCDL1 including the gate electrodes GAE (e.g., electrodes, conductive patterns and/or at least one line provided in the first gate conductive layer GCDL1) may be covered by the second insulating layer 124.

The gate electrode GAE may include at least one conductive material and may be formed in a single-layer or multi-layer pattern. The patterns of the first gate conductive layer GCDL1 may include the same conductive material and may have the same cross-sectional structure.

According to the embodiment of the disclosure, the second transistor PLT may further include a source electrode SE2 and a drain electrode DE2 electrically connected to different regions of the active layer PACT. For example, the second transistor PLT may include the source electrode SE2 electrically connected to the source region SRA of the active layer PACT and the drain electrode DE2 electrically connected to the drain region DRA of the active layer PACT. According to an embodiment, the second transistor PLT may include no separate source electrode SE2 and/or drain electrode DE2, and the source region SRA and/or the drain region DRA of the active layer PACT may work as the source electrode and/or the drain electrode of the second transistor PLT.

According to an embodiment of the disclosure, the source electrode SE2 and the drain electrode DE2 may be provided in the source-drain conductive layer SCDL. For example, the source electrodes SE1 and SE2 and the drain electrodes DE1 and DE2 of the pixel transistors T, including the first transistor OXT and the second transistor PLT, may be disposed in a same conductive layer.

The capacitor Cst may include a first capacitor electrode CAE1 and a second capacitor electrode CAE2. The first capacitor electrode CAE1 and the second capacitor electrode CAE2 may overlap each other with at least one insulating layer (e.g., the second insulating layer 124) disposed between the first capacitor electrode CAE1 and the second capacitor electrode CAE2.

According to the embodiment of the disclosure, the first capacitor electrode CAE1 may be provided in the first gate conductive layer GCDL1, and the second capacitor electrode CAE2 may be provided in the second gate conductive layer GCDL2. It should be noted that the positions of the first capacitor electrode CAE1 and/or the second capacitor electrode CAE2 may vary depending on embodiments. Each of the first capacitor electrode CAE1 and the second capacitor electrode CAE2 may be implemented as a single electrode provided in a conductive layer, or may be implemented as multiple electrodes including sub-electrodes provided in multiple conductive layers.

According to an embodiment of the disclosure, the first capacitor electrode CAE1 and the gate electrode GAE of at least one second transistor PLT may be integral with each other. For example, the first capacitor electrode CAE1 and the gate electrode of the first pixel transistor T1 shown in FIG. 3 may be integral with each other. For example, the first capacitor electrode CAE1 and the gate electrode of the first pixel transistor T1 may be formed as a single integrated conductive pattern, and the second capacitor electrode CAE2 may be disposed to overlap the conductive pattern.

The first insulating layer 123 may be disposed on the buffer layer 122 and the first semiconductor layer SCL1. The first insulating layer 123 may cover the patterns of the first semiconductor layer SCL1 (e.g., the active layer PACT of the second transistor PLT).

The second insulating layer 124 may be disposed on the first insulating layer 123 and the first gate conductive layer GCDL1. The second insulating layer 124 may cover the patterns of the first gate conductive layer GCDL1 (e.g., the gate electrode GAE of the second transistor PLT and the first capacitor electrode CAE1).

The third insulating layer 125 may be disposed on the second insulating layer 124 and the second gate conductive layer GCDL2. The third insulating layer 125 may cover the patterns of the second gate conductive layer GCDL2 (e.g., the bottom gate electrode BG of the first transistor OXT and the second capacitor electrode CAE2).

The fourth insulating layer 126 may be disposed on the third insulating layer 125 and the second semiconductor layer SCL2. The fourth insulating layer 126 may cover the patterns of the second semiconductor layer SCL2 (e.g., the active layer OACT of the first transistor OXT).

The fifth insulating layer 127 may be disposed on the fourth insulating layer 126 and the third gate conductive layer GCDL3. The fifth insulating layer 127 may cover the patterns of the third gate conductive layer GCDL3 (e.g., the gate electrode GE of the first transistor OXT).

According to the embodiment of the disclosure, the first insulating layer 123, the second insulating layer 124, the third insulating layer 125, the fourth insulating layer 126 and the fifth insulating layer 127 may be inorganic insulating layers including an inorganic insulating material (e.g., silicon nitride, silicon oxide, silicon oxynitride, titanium oxide, aluminum oxide, other inorganic insulating materials), or a combination thereof. Each of the first insulating layer 123, the second insulating layer 124, the third insulating layer 125, the fourth insulating layer 126 and the fifth insulating layer 127 may have a single-layer or multi-layer structure.

The sixth insulating layer 128 may be disposed on the fifth insulating layer 127 and the source-drain conductive layer SCDL. The sixth insulating layer 128 may cover the patterns of the source-drain conductive layer SCDL (e.g., the source electrode SE1 and the drain electrode DE1 of the first transistor OXT, and the source electrode SE2 and the drain electrode DE2 of the second transistor PLT).

According to an embodiment of the disclosure, the sixth insulating layer 128 may be an organic insulating layer containing organic insulating materials (e.g., an acryl resin, an epoxy resin, a phenolic resin, a polyamide resin, a polyimide resin, other organic insulating materials, or a combination thereof), and each may have a single-layer or multi-layer structure. The upper surface of the sixth insulating layer 128 may be substantially flat.

The emission material layer 130 may be disposed on the circuit layer 120 and may be located in the display area DA. For example, the emission material layer 130 may be disposed on the circuit layer 120 in the display area DA.

The emission material layer 130 may include light-emitting elements EL of the pixels PX. For example, the emission material layer 130 may include a pixel-defining layer 131 that partitions the emission area EA of each of the pixels PX, and light-emitting elements EL each located in the emission area EA. According to the embodiment of the disclosure, the emission material layer 130 may further include a spacer 132 disposed on a portion of the pixel-defining layer 131.

Each of the light-emitting elements EL may include a first electrode ET1 electrically connected to at least one pixel transistor T included in that pixel PX (e.g., the second transistor PLT in FIG. 4), an emissive layer EML sequentially disposed on the first electrode ET1, and a second electrode ET2. According to the embodiment of the disclosure, the first electrode ET1 of the light-emitting element EL may be an anode electrode, and the second electrode ET2 may be a cathode electrode, but the disclosure is not limited thereto.

The first electrode ET1 of each of the light-emitting element EL may include a conductive material and may be disposed on the circuit layer 120. For example, the first electrode ET1 may be disposed on the sixth insulating layer 128 in each of the emission areas EA. The first electrode ET1 may be electrically connected to an electrode (e.g., the drain electrode DE2) of the second transistor PLT through a contact hole or a via hole penetrating the sixth insulating layer 128.

According to an embodiment of the disclosure, the first electrode ET1 may include a metal material having high reflectivity. For example, the first electrode ET1 may have a single-layer structure of molybdenum (Mo), titanium (Ti), copper (Cu), or aluminum (Al), or a combination thereof, or may have a multi-layer structure including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), nickel (Ni), or a combination thereof, etc. (e.g., ITO/Mg, ITO/MgF, ITO/Ag, ITO/Ag/ITO, etc.).

The emissive layer EML of each of the light-emitting elements EL may include a high-molecular substance or a low-molecular substance. Light emitted from the emissive layer EML may contribute to displaying images. According to an embodiment of the disclosure, the emissive layer EML may be disposed in each of the pixels PX, and the emissive layer EML of each of the pixels PX may emit visible light of a color associated with the respective pixel PX. According to an embodiment, the emissive layer EML may be a common layer shared by the pixels PX of different colors, and wavelength conversion layers and/or color filters corresponding to the colors (or wavelength bands) of light to be emitted from the pixels PX may be disposed in the emission areas EA of at least some of the pixels PX.

The second electrode ET2 of each of the light-emitting elements EL may include a conductive material and may be electrically connected to the second pixel voltage line VSL. According to the embodiment of the disclosure, the second electrode ET2 may be a common layer formed over the entire display area DA to cover the emissive layer EML and the pixel-defining layer 131. According to the embodiment of the disclosure, the second electrode ET2 may be formed of a transparent conductive material (TCO) such as ITO and IZO that can transmit light, or a semi-transmissive conductive material such as magnesium (Mg), silver (Ag), an alloy of magnesium (Mg) and silver (Ag), or a combination thereof.

The pixel-defining layer 131 may have openings associated with the emission areas EA and may surround the emission areas EA. For example, the pixel-defining layer 131 may be formed to cover an edge of the first electrode ET1 of the light-emitting element EL, and may include an opening that exposes the remaining portion of the first electrode ET1. The area where the exposed first electrode ET1 and the emissive layer EML overlap each other (or an area including the same) may be defined as the emission area EA of each pixel PX.

According to an embodiment of the disclosure, the pixel-defining layer 131 may include at least one organic film containing an organic insulating material. For example, the pixel-defining layer 131 may include an organic insulating material such as polyacrylate resin, epoxy resin, phenolic resin, polyamide resin, polyimide resin, unsaturated polyesters resin, polyphenylene ether resin, poly phenylene sulfide resin and benzocyclobutene (BCB), other organic insulating material, or a combination thereof.

The spacer 132 may be disposed on a part of the pixel-defining layer 131. The spacer 132 may include at least one organic film containing an organic insulating material. The spacer 132 and the pixel-defining layer 131 may include a same material or may include a different material from the pixel-defining layer 131. According to the embodiment of the disclosure, the pixel-defining layer 131 and the spacer 132 may be formed sequentially via respective mask processes. According to an embodiment, the pixel-defining layer 131 and the spacer 132 may be formed simultaneously using a halftone mask. In this instance, the pixel-defining layer 131 and the spacer 132 may be integral with each other.

The encapsulation layer 140 may be disposed on the emission material layer 130 in the main area MA. The encapsulation layer 140 may cover the emission material layer 130 and may extend to the non-display area NA to be in contact with the circuit layer 120. According to the embodiment, the encapsulation layer 140 may include a first inorganic encapsulation film 141, an organic encapsulation film 142, and a second inorganic encapsulation film 143 sequentially disposed on the emission material layer 130. The first inorganic encapsulation film 141 and the second inorganic encapsulation film 143 may include an inorganic material, and the organic encapsulation film 142 may include an organic material. The encapsulation layer 140 can block the permeation of oxygen or moisture into the emission material layer 130 and can alleviate electrical and/or physical shock on the circuit layer 120 and the emission material layer 130.

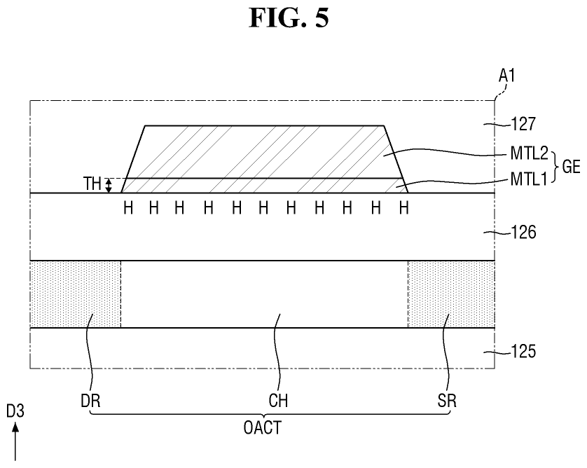

FIG. 5 is a schematic cross-sectional view showing area A1 of FIG. 4. For example, FIG. 5 is an enlarged view showing in detail the gate electrode GE of the first transistor OXT and the periphery of the gate electrode GE.

Referring to FIGS. 4 and 5, the gate electrode GE of the first transistor OXT may include a first metal layer MTL1 disposed on the fourth insulating layer 126. For example, the first metal layer MTL1 may be disposed on (e.g., directly on) the fourth insulating layer 126. According to the embodiment of the disclosure, the gate electrode GE of the first transistor OXT may further include a second metal layer MTL2 disposed on the first metal layer MTL1. For example, the gate electrode GE of the first transistor OXT may include the first metal layer MTL1 and the second metal layer MTL2 sequentially arranged or stacked on each other on the fourth insulating layer 126, and may have at least double-layer structure.

The first metal layer MTL1 may include a material with high hydrogen adsorption capacity. For example, the first metal layer MTL1 may include titanium (Ti). The first metal layer MTL1 may include another material with high hydrogen adsorption capacity.

According to an embodiment of the disclosure, during a process of fabricating the display panel 100, including a film formation process of the second metal layer MTL2 and a film formation process of the fifth insulating layer 127, the first metal layer MTL1 may be formed with a thickness TH sufficient to properly adsorb hydrogen (H) injected into the fourth insulating layer 126, etc. For example, the first metal layer MTL1 may have a thickness TH of about 300 Å or more.

As the first metal layer MTL1 adsorbs hydrogen (H), it may be possible to prevent or reduce the hydrogen (H) excessively injected into the fourth insulating layer 126 from reacting with the active layer OACT of the first transistor OXT to change the characteristics of the first transistor OXT. For example, as the first metal layer MTL1 properly adsorbs hydrogen (H), during the process of fabricating the display panel 100, it may be possible to prevent or reduce hydrogen (H) from diffusing into the active layer OACT of the first transistor OXT formed of an oxide semiconductor to change the carrier concentration or the threshold voltage of the first transistor OXT. In this manner, the characteristics of the first transistor OXT can become uniform and/or can be stabilized, and the operating characteristics of the pixels PX can become uniform and/or can be stabilized.

As the area of the gate electrode GE including the first metal layer MTL1 (or a conductive pattern including the first metal layer MTL1 like the gate electrode GE) increases, the amount of hydrogen (H) adsorbed on the first metal layer MTL1 may increase. If the first metal layer MTL1 has a sufficient thickness TH of about 300 Å or more, the amount of hydrogen (H) adsorbed on the first metal layer MTL1 may increase. Accordingly, the characteristics of the first transistor OXT can become more uniform and/or can be stabilized.

The second metal layer MTL2 may include a low-resistance material that has lower resistance than the material of the first metal layer MTL1 (e.g., titanium (Ti)). As an example, the second metal layer MTL2 may include molybdenum (Mo), aluminum (Al), other low-resistance metal, or a combination thereof. According to an embodiment of the disclosure, the second metal layer MTL2 may be formed to have a thickness greater than or equal to the thickness TH of the first metal layer MTL1. Accordingly, the resistance of the gate electrode GE and the third gate conductive layer GCDL3 including it can be lowered.

The patterns of the third gate conductive layer GCDL3, including the gate electrode GE of the first transistor OXT, may be formed simultaneously using a same material as the gate electrode GE and may have substantially the same cross-sectional structure. As an example, the patterns of the third gate conductive layer GCDL3 may have a double-layer structure including the first metal layer MTL1 containing titanium (Ti) and the second metal layer MTL2 containing molybdenum (Mo) or aluminum (Al), etc. According to an embodiment of the disclosure, the patterns of the third gate conductive layer GCDL3 may have a triple-layer structure that further includes at least one metal layer disposed on the second metal layer MTL2, or more. As an example, the patterns of the third gate conductive layer GCDL3 may have a triple-layer structure including a first metal layer MTL1 containing titanium (Ti), a second metal layer MTL2 containing molybdenum (Mo) or aluminum (Al), and a third metal layer containing titanium (Ti) disposed on the second metal layer MTL2.

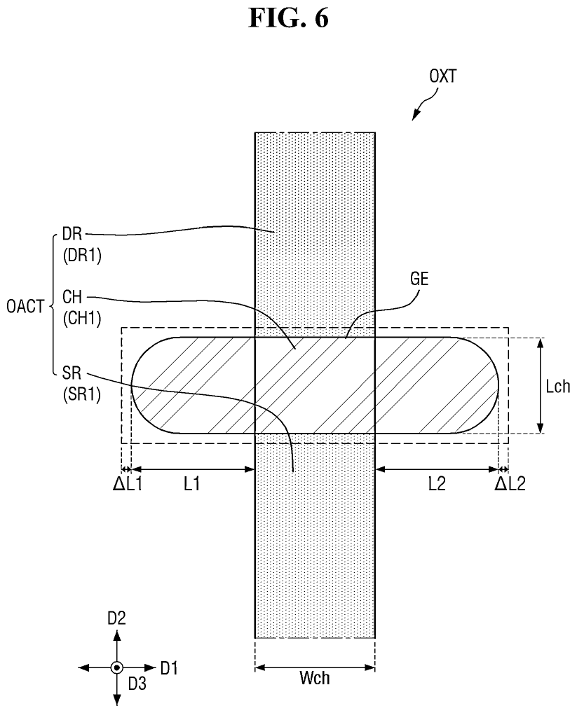

FIG. 6 is a plan view showing a first transistor OXT according to an embodiment of the disclosure.

Referring to FIGS. 4 to 6, the first transistor OXT may include an active layer OACT and a gate electrode GE disposed on a part of the active layer OACT. According to an embodiment of the disclosure, the active layer OACT and the gate electrode GE may extend in different directions. For example, the active layer OACT may extend in the second direction D2, and the gate electrode GE may extend in the first direction D1 and intersect the active layer OACT.

Although the active layer OACT and the gate electrode GE of the first transistor OXT may extend in the second direction D2 and the first direction D1, respectively, and have a generally rectangular shape (or a rectangular shape with rounded corners) in the embodiment of FIG. 6, embodiments of the disclosure are not limited thereto. For example, the shapes, sizes and/or extension directions of the active layer OACT and the gate electrode GE of the first transistor OXT may vary depending on embodiments.

According to an embodiment of the disclosure, the first transistor OXT may further include a source electrode (e.g., the source electrode SE1 of FIG. 4) and a drain electrode (e.g., the drain electrode DE of FIG. 4) electrically connected to the source region SR and the drain region DR of the active layer OACT, respectively. As an example, the source region SR and/or the drain region DR of the first transistor OXT may be electrically connected to other circuit elements, conductive patterns, and/or lines, etc. to work as the source electrode and/or the drain electrode of the first transistor OXT.

The active layer OACT may include a channel region CH (or first channel region CH1) overlapping the gate electrode GE, and a drain region DR (or first drain region DR1) and a source region SR (or first source region SR1) may be disposed on both (or opposing) sides of the channel region (CH).

The channel region CH may have a channel length Lch and a channel width Wch equal to those of a flow path of current. According to the embodiment of the disclosure, the length direction of the channel region CH may correspond to the second direction D2, and the width direction of the channel region CH may correspond to the first direction D1, but the embodiments of the disclosure are not limited thereto.

The gate electrode GE may overlap a part of the active layer OACT including the channel region CH. The gate electrode GE may protrude on both sides of the active layer OACT by a first length L1 and a second length L2, respectively, in the width direction of the channel region CH (e.g., in the first direction D1). The first length L1 may be equal to or different from the second length L2.

According to an embodiment of the disclosure, the gate electrode GE may protrude by more than about 4 μm on both sides of the active layer OACT in the width direction of the channel region CH. For example, each of the first length L1 and the second length L2 may be equal to or greater than about 4 μm.

According to an embodiment of the disclosure, in consideration of the amount of deviations that may occur during the etching process of the conductive film to form the gate electrode GE (for example, the skew amount of the conductive film corresponding to ΔL1 and ΔL2 in FIG. 6), the gate electrode GE may be designed to have a larger size than the target value. For example, presuming a skew amount of approximately about 0.6 μm on a side, or a skew amount in the range of about 0.6 μm to about 1 μm, the gate electrode GE may be designed to protrude more than about 5 μm on both sides of the active layer ACT in the first direction D1 as indicated by the dashed line in FIG. 6. Accordingly, the gate electrode GE that protrudes by about 4 μm or more on both sides of the active layer OACT in the width direction of the channel region CH may be formed. For example, let us assume that the skew amount on a side generated during a dry etching process of the conductive film may be about 0.6 μm, and the gate electrode GE may be designed to protrude about 5 μm or more on both sides of the active layer ACT. Then, the finally formed gate electrode GE may protrude about 4.4 μm or more on both sides of the active layer ACT. Similarly, in the second direction D2, the gate electrode GE may be designed with a width greater than the target value taking into account the skew amount of the conductive film that may occur during the process.

According to embodiments, the channel region CH of the active layer ACT and the periphery of the channel region CH can be stably covered by the gate electrode GE. As a result, the channel length Lch and the channel width Wch that meet the target values can be properly obtained, and the amount of hydrogen (H) adsorbed by the gate electrode GE can be increased. In this manner, the characteristics of the first transistor OXT can become uniform and/or can be stabilized.

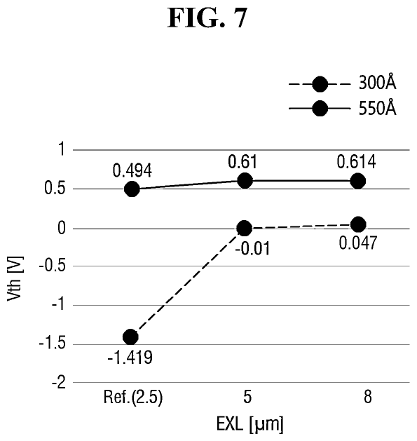

FIG. 7 is a graph showing changes in characteristics of the first transistor OXT with respect to the length of the gate electrode GE and the thickness TH of the first metal layer MTL1. For example, FIG. 7 shows changes in the threshold voltage Vth versus the thickness TH of the first metal layer MTL1 of the first transistor OXT that is designed to protrude on both sides of the active layer OACT with an extension length EXL corresponding to each margin value.

Referring to FIGS. 4 to 7, for the first transistor OXT that is designed so that the gate electrode GE protrudes on both sides of the active layer OACT with an extension length EXL corresponding to a reference margin value (e.g., about 2.5 μm), the threshold value Vth may change relatively greatly with respect to changes in the thickness of the gate electrode GE. In contrast, for the first transistor OXT that is designed so that the gate electrode GE protrudes on both sides of the active layer OACT with an extension length EXL of about 5 μm or more (e.g., about 5 μm or about 8 μm), the threshold value Vth may change relatively little with respect to changes in the thickness of the gate electrode GE. For the first transistor OXT that is designed so that the gate electrode GE protrudes on both sides of the active layer OACT with an extension length EXL of about 5 μm or more, the gate electrode GE can protrude on both sides of the active layer OACT by the length of about 4 μm or more even if the size of the gate electrode GE may be reduced due to the skew amount that occurs during the process of fabricating the display panel 100. The threshold voltage Vth of the first transistor OXT may vary depending on the thickness TH of the gate electrode GE as well.

According to an embodiment of the disclosure, if the gate electrode GE is designed to protrude on both sides of the active layer OACT by an extension length EXL of about 5 μm or more, and/or the thickness TH of the first metal layer MTL1 of the gate electrode GE is equal to or greater than about 300 Å, the first transistor OXT can exhibit uniform characteristics. In this manner, the operating characteristics of the pixels PX each including at least one first transistor OXT can become uniform and/or can be stabilized.

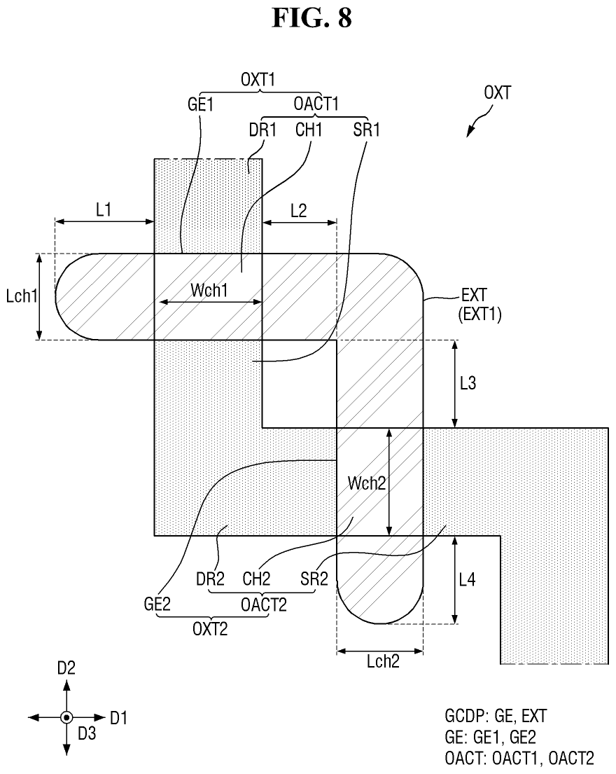

FIGS. 8 to 14 are plan views showing first transistors OXT according to embodiments of the disclosure. For example, FIGS. 8 to 14 show different embodiments of a dual-type first transistor OXT and a gate conductive pattern GCDP including a gate electrode GE of the first transistor OXT.

Referring to FIGS. 8 to 14 in conjunction with FIGS. 4 to 7, the first transistor OXT may be formed in a dual structure including a first sub-transistor OXT1 and a second sub-transistor OXT2 electrically connected in series. The first sub-transistor OXT1 may include a first active layer OACT1 and a first gate electrode GE1 disposed on a part of the first active layer OACT1. The second sub-transistor OXT2 may include a second active layer OACT2 and a second gate electrode GE2 disposed on a part of the second active layer OACT2. As the first transistor OXT may be formed in the dual structure, even if a defect (for example, a short circuit due to a foreign material) occurs in one of the first sub-transistor OXT1 and the second sub-transistor OXT2, the first transistor OXT can operate normally by the other sub-transistor.

The active layer OACT of the first transistor OXT may include the first active layer OACT1 of the first sub-transistor OXT1, and the second active layer OACT2 of the second sub-transistor OXT2. The gate electrode GE of the first transistor OXT may include the first gate electrode GE1 of the first sub-transistor OXT1, and the second gate electrode GE2 of the second sub-transistor OXT2.

According to the embodiment of the disclosure, the first sub-transistor OXT1 and the second sub-transistor OXT2 may be integral with each other. For example, the first active layer OACT1 of the first sub-transistor OXT1 and the second active layer OACT2 of the second sub-transistor OXT2 may be integral with each other, and the first gate electrode GE1 of the first sub-transistor OXT1 and the second gate electrode GE2 of the second sub-transistor OXT2 may be integral with each other.

The first active layer OACT1 may include a first channel region CH1 overlapping the first gate electrode GE1, a first drain region DR1 and a first source region SR1 disposed on both sides of the first channel region CH1. The first channel region CH1 may have a first channel length Lch1 and a first channel width Wch1. According to the embodiment of the disclosure, the length direction of the first channel region CH1 may correspond to the second direction D2, and the width direction of the first channel region CH1 may correspond to the first direction D1, but the disclosure is not limited thereto.

The second active layer OACT2 may include a second channel region CH2 overlapping the second gate electrode GE2, a second drain region DR2 and a second source region SR2 disposed on both sides of the second channel region CH2. The second channel region CH2 may be spaced apart from the first channel region CH1. For example, the first channel region CH1 and the second channel region CH2 may be spaced apart from each other with the first source region SR1 and the second drain region DR2 between the first channel region CH1 and the second channel region CH2. According to an embodiment of the disclosure, the first source region SR1 and the second drain region DR2 may be substantially the same region. The second channel region CH2 may have a second channel length Lch2 and a second channel width Wch2.

According to an embodiment of the disclosure, the portion of the active layer OACT of the first transistor OXT that includes the first active layer OACT1 and the second active layer OACT2 may have a shape that may be bent or curved at least once, as shown in FIGS. 8 to 11. For example, the first active layer OACT1 and the second active layer OACT2 may extend in substantially different directions. According to an embodiment of the disclosure, the length direction of the second channel region CH2 may be different from the length direction of the first channel region CH1, and the width direction of the second channel region CH2 may be different from the width direction of the first channel region CH1. For example, the length direction of the second channel region CH2 may correspond to the first direction D1, and the width direction of the second channel region CH2 may correspond to the second direction D2.

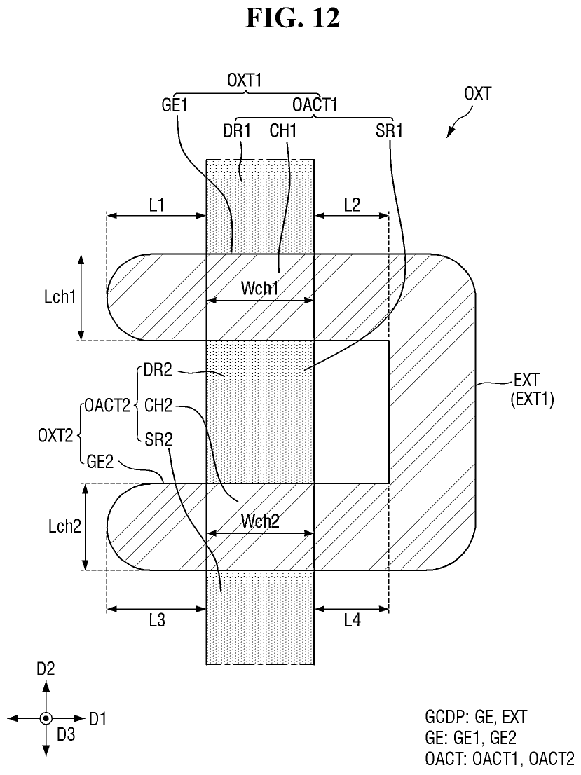

According to an embodiment, as shown in FIGS. 12 to 14, the first active layer OACT1 and the second active layer OACT2 may extend substantially in the same direction. For example, the portion of the active layer OACT of the first transistor OXT that includes the first active layer OACT1 and the second active layer OACT2 may not be substantially bent and may uniformly extend in a direction (for example, the second direction D2).

An insulating layer may be disposed on the active layer OACT of the first transistor OXT that includes the first active layer OACT1 and the second active layer OACT2, and the gate conductive pattern GCDP including the gate electrode GE of the first transistor OXT may be disposed on the insulating layer. For example, the fourth insulating layer 126 of FIGS. 4 and 5 may be disposed on the active layer OACT of the first transistor OXT, and the gate conductive pattern GCDP including the gate electrode GE of the first transistor OXT may be disposed on the fourth insulating layer 126. According to an embodiment of the disclosure, the gate conductive pattern GCDP may be provided as the third gate conductive layer GCDL3 of FIG. 4, but the disclosure is not limited thereto.

The gate conductive pattern GCDP may include a first gate electrode GE1, a second gate electrode GE2, and an expanded pattern portion EXT. According to an embodiment, the first gate electrode GE1, the second gate electrode GE2 and the expanded pattern portion EXT may be integral with each other. For example, the first gate electrode GE1, the second gate electrode GE2 and the extended pattern portion EXT may be different parts of the gate conductive pattern GCDP.

The first gate electrode GE1 may overlap a part of the active layer OACT including the first channel region CH1, and may protrude on both sides of the active layer OACT in the width direction of the first channel region CH1 (e.g., in the first direction D1). For example, the first gate electrode GE1 may protrude on both sides of the active layer OACT by the first length L1 and the second length L2, respectively, in the width direction of the first channel region CH1. According to an embodiment of the disclosure, each of the first length L1 and the second length L2 may be equal to or greater than about 4 μm. Accordingly, the first channel region CH1 can be stably covered by the first gate electrode GE1.

The second gate electrode GE2 may overlap a part of the active layer OACT including the second channel region CH2, and may protrude on both sides of the active layer OACT in the width direction of the second channel region CH2 (e.g., in the second direction D2). For example, the second gate electrode GE2 may protrude on both sides of the active layer OACT by a third length L3 and a fourth length L4, respectively, in the width direction of the second channel region CH2. The third length L3 may be equal to or different from the fourth length L4. According to an embodiment of the disclosure, each of the third length L3 and the fourth length L4 may be equal to or greater than about 4 μm. Accordingly, the second channel region CH2 can be stably covered by the second gate electrode GE2.

The expanded pattern portion EXT may extend from at least the first gate electrode GE1 and may be disposed in the vicinity of the active layer OACT. The expanded pattern portion EXT may have a variety of shapes and/or sizes depending on embodiments. As an example, the expanded pattern portion EXT may have at least one pattern disclosed in at least one of the embodiments of FIGS. 8 to 14. The expanded pattern portion EXT may not overlap the active layer OACT, but the disclosure is not limited thereto.

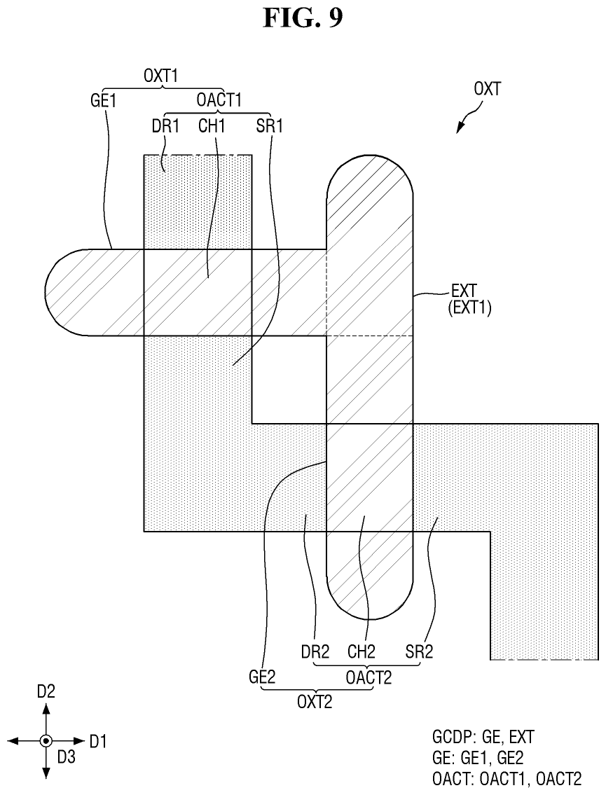

According to an embodiment of the disclosure, the expanded pattern portion EXT may be formed as a first pattern EXT1 that may be located on a side of the first gate electrode GE1 in the first direction D1 corresponding to the width direction of the first channel region CH1 and may not overlap the active layer OACT, as shown in FIGS. 8 and 9.

According to an embodiment of the disclosure, the expanded pattern portion EXT may be located between the first gate electrode GE1 and the second gate electrode GE2. For example, the first pattern EXT1 may be disposed between the first gate electrode GE1 and the second gate electrode GE2, and may electrically connect the first gate electrode GE1 with the second gate electrode GE2.

According to an embodiment of the disclosure, the first pattern EXT1 may be locally disposed only at a location in parallel to the first channel region CH1 and the second channel region CH2 in the first direction D1 and the second direction D2. For example, the first pattern EXT1 may have a width and/or a length that may be equal to or less than the first channel length Lch1 and the second channel length Lch2, as shown in FIG. 8.

According to an embodiment of the disclosure, the first pattern EXT1 may be disposed parallel to at least a portion of the active layer OACT when viewed from the top (or in a plan view). For example, as shown in FIG. 9, the first pattern EXT1 may be expanded in the second direction DR2 so that it may be parallel to the first drain region DR1 when viewed from the plane defined by the first direction D1 and the second direction D2 (or in a plan view).

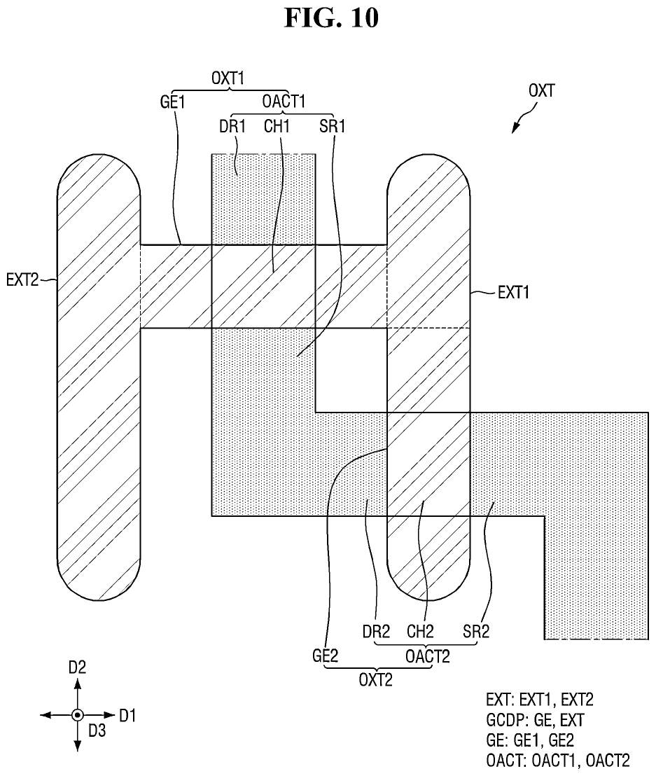

According to an embodiment of the disclosure, as shown in FIG. 10, the expanded pattern portion EXT may further include a second pattern EXT2 that may be disposed on the opposite side of the first gate electrode GE1 in the first direction DR1 corresponding to the width direction of the first channel region CH1 and may not overlap the active layer OACT. According to an embodiment of the disclosure, the second pattern EXT2 may be arranged parallel to at least a portion of the active layer OACT when viewed from the top (or in a plan view). For example, the second pattern EXT2 may extend in the second direction DR2 so that it may be parallel to the first active layer OACT1 when viewed from the plane defined by the first direction D1 and the second direction D2.

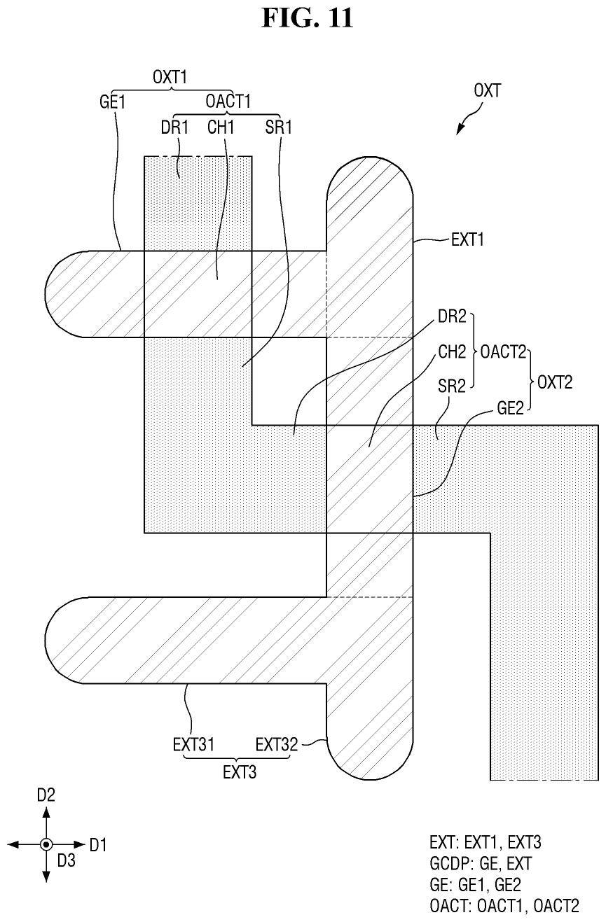

According to an embodiment of the disclosure, the expanded pattern portion EXT may further include a third pattern EXT3 that may extend from the second gate electrode GE2 and may be spaced apart from the first pattern EXT1 with the second gate electrode GE2 the first pattern EXT1 and the third pattern EXT3 as shown in FIG. 11.

According to an embodiment of the disclosure, the third pattern EXT3 may be arranged parallel to at least a portion of the active layer OACT when viewed from the top. For example, the third pattern EXT3 may include at least one of a first portion EXT31 extending in the first direction DR1 such that it may be in parallel to a portion of the second drain region DR2, and a second portion EXT32 extending in the second direction DR2 such that it may be in parallel to a portion of the second source region SR2.

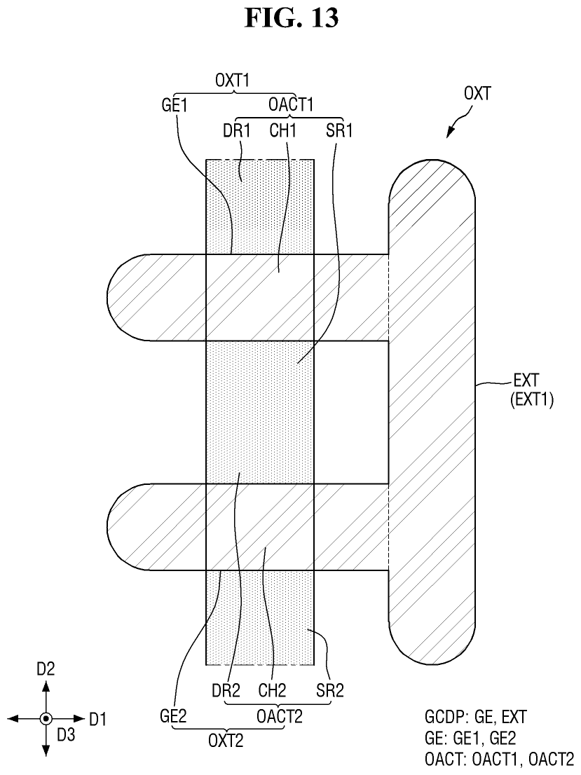

According to an embodiment of the disclosure, as shown in FIGS. 12 to 14, the first gate electrode GE1 and the second gate electrode GE2 may be substantially parallel to each other. For example, the first gate electrode GE1 and the second gate electrode GE2 may extend in the first direction D1, and may be spaced apart from each other with at least a portion of the expanded pattern portion EXT (e.g., the first pattern EXT1) between the first gate electrode GE1 and the second gate electrode GE2. The expanded pattern portion EXT may include a first pattern EXT1 that may be disposed on a side of the first gate electrode GE1 and the second gate electrode GE2 and may extend in a direction different from the first gate electrode GE1 and the second gate electrode GE2 (e.g., in the second direction D2). The size or shape of the first pattern EXT1 may vary depending on embodiments. For example, as shown in FIG. 13, the first pattern EXT1 may have an expanded length at at least an end in the longitudinal direction (e.g., the second direction D2) such that it may be parallel to at least one of the first drain region DR1 and the second source region SR2.

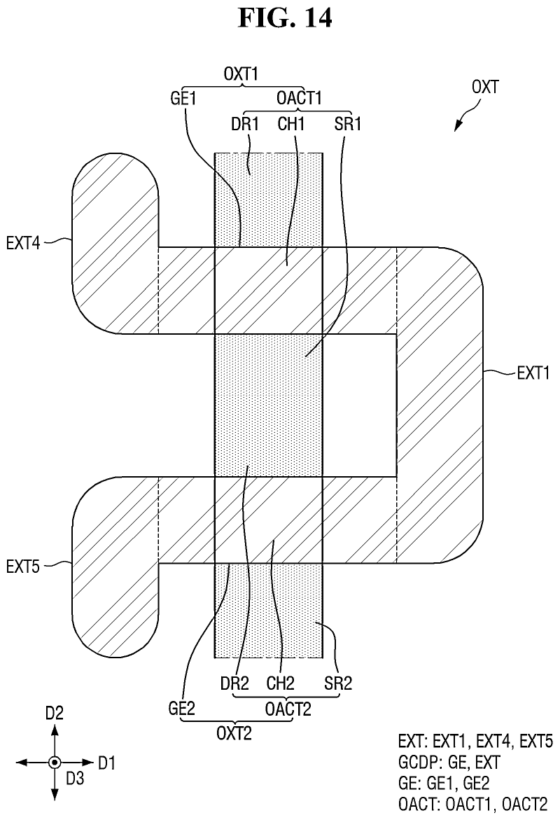

According to an embodiment of the disclosure, as shown in FIG. 14, the expanded pattern portion EXT may further include a fourth pattern EXT4 that may be disposed on the opposite side of the first gate electrode GE1 in the width direction (e.g., the first direction D1) of the first channel region CH1 and may not overlap the active layer OACT and a fifth pattern EXT5 that may be disposed on the opposite side of the second gate electrode GE2 in the width direction (e.g., the first direction D1) of the second channel region CH2 and may not overlap the active layer OACT. As an example, the extended pattern portion EXT may include only one of the fourth pattern EXT4 and the fifth pattern EXT5 and may not include the other. As an example, the fourth pattern EXT4 and the fifth pattern EXT5 may be electrically connected to each other as a pattern. For example, the first source region SR1 and the second drain region DR2 may be completely surrounded by the gate conductive pattern GCDP when viewed from the top.

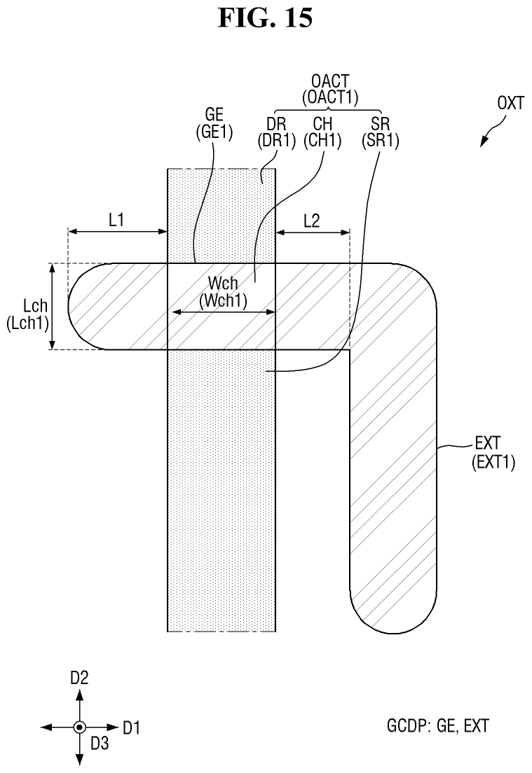

FIGS. 15 to 17 are plan views showing first transistors OXT according to embodiments of the disclosure. For example, FIGS. 15 to 17 show different embodiments of a single-type first transistor OXT and a gate conductive pattern GCDP including a gate electrode GE of the first transistor OXT.

Referring to FIGS. 15 to 17 in conjunction with FIGS. 4 to 14, the first transistor OXT may include an active layer OACT (e.g., a first active layer OACT1) including a single channel region CH and a single gate electrode GE (e.g., a first gate electrode GE1) disposed on a portion of the active layer OACT. For example, the active layer OACT of the first transistor OXT may include a channel region CH (e.g., the first channel region CH1) overlapping the gate electrode GE, and a drain region DR (e.g., the first drain region DR1) and a source region SR (e.g., the first source region SR1) disposed on both sides of the channel region CH, respectively. The channel region CH may have a channel length Lch (e.g., a first channel length Lch1) and a channel width Wch (e.g., a first channel width Wch1).

An insulating layer (e.g., the fourth insulating layer 126 of FIGS. 4 and 5) may be disposed on the active layer OACT of the first transistor OXT, and the gate conductive pattern GCDP including the gate electrode GE of the first transistor OXT may be disposed on the insulating layer. According to an embodiment of the disclosure, the gate conductive pattern GCDP may be provided as the third gate conductive layer GCDL3 of FIG. 4, but the disclosure is not limited thereto.

The gate conductive pattern GCDP may include the gate electrode GE and an expanded pattern portion EXT (e.g., the first pattern EXT1). According to an embodiment of the disclosure, the gate electrode GE and the expanded pattern portion EXT may be integral with each other.

The gate electrode GE may overlap a portion of the active layer OACT including the channel region CH, and may protrude on both sides of the active layer OACT in the width direction of the channel region CH (e.g., in the first direction D1). For example, the gate electrode GE may protrude on both sides of the active layer OACT by the first length L1 and the second length L2, respectively, in the width direction of the channel region CH. According to an embodiment of the disclosure, each of the first length L1 and the second length L2 may be equal to or greater than about 4 μm. Accordingly, the channel region CH can be stably covered by the gate electrode GE.

The expanded pattern portion EXT may extend from the gate electrode GE and may be disposed in the vicinity of the active layer OACT. The expanded pattern portion EXT may have a variety of shapes and/or sizes depending on embodiments. For example, the expanded pattern portion EXT may include a first pattern EXT1 that may be disposed on a side of the gate electrode GE and may extend in a direction different from the gate electrode GE (e.g., in the second direction D2).

According to an embodiment of the disclosure, the expanded pattern portion EXT may not overlap the active layer OACT. For example, as shown in FIG. 15, the expanded pattern portion EXT may be disposed on a side of the active layer ACT and may not overlap the active layer ACT.

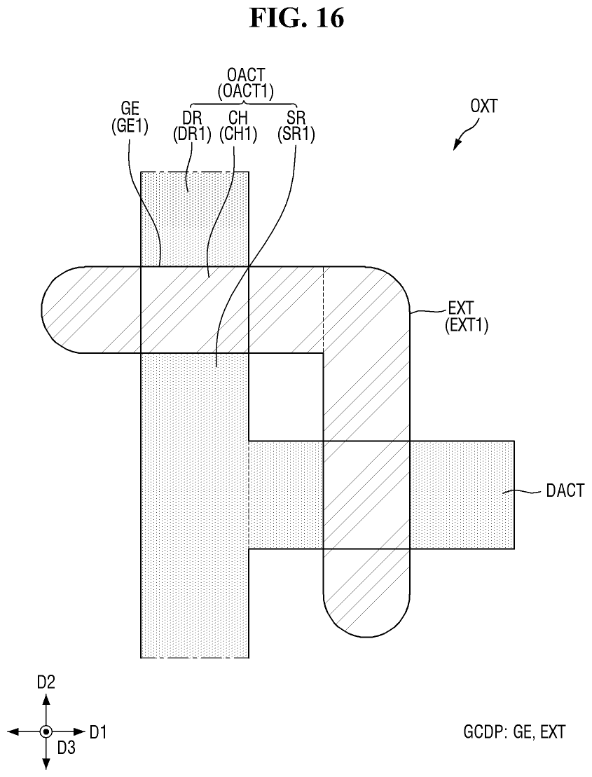

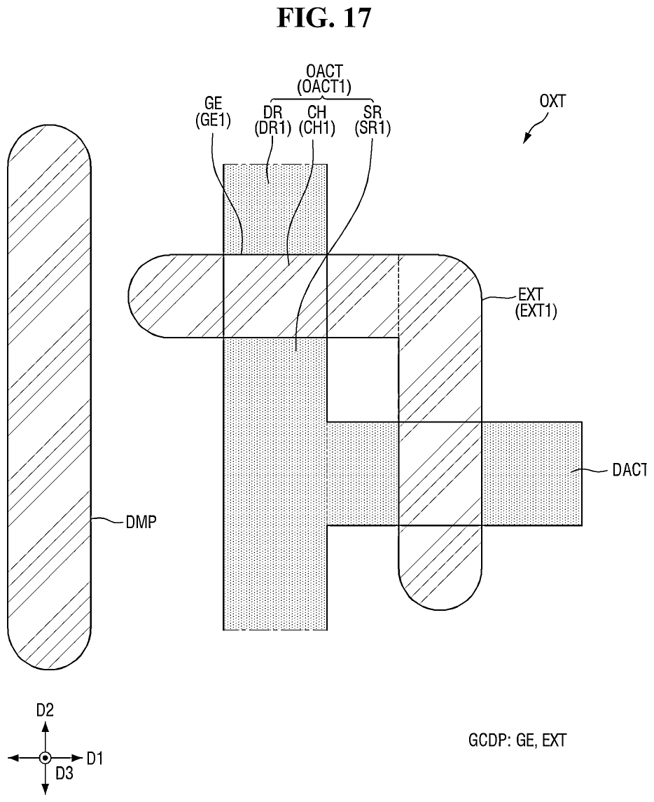

According to an embodiment of the disclosure, the expanded pattern portion EXT may overlap the active layer OACT. For example, as shown in FIGS. 16 and 17, the active layer OACT may include a dummy pattern portion DACT that may extend from the source region SR (or the drain region DR) and may overlap the expanded pattern portion EXT. An end of the dummy pattern portion DACT may be floating. The expanded pattern portion EXT may overlap at least a portion of the dummy pattern portion DACT.

According to an embodiment of the disclosure, as shown in FIG. 17, a dummy pattern DMP separated from a gate conductive pattern GCDP may be further disposed in the vicinity of the first transistor OXT. The dummy pattern DMP may be provided in the same conductive layer as the gate conductive pattern GCDP. For example, the dummy pattern DMP may be provided in the third gate conductive layer GCDL3 disposed on the fourth insulating layer 126 of FIG. 4. The dummy pattern DMP and the gate conductive pattern GCDP may be formed simultaneously using a same material. Accordingly, the dummy pattern DMP and the gate conductive pattern GCDP may include a same material and may have substantially the same cross-sectional structure. For example, the dummy pattern DMP may include a first metal layer MTL1 and a second metal layer MTL2 of FIG. 5.

According to an embodiment of the disclosure, the dummy pattern DMP may be floating. As an example, the dummy pattern DMP may be electrically connected to a line from which a bias voltage or the like may be applied. According to an embodiment of the disclosure, the dummy pattern DMP may be disposed in the display area DA or in the vicinity of the display area DA. According to an embodiment of the disclosure, the dummy pattern DMP may be formed as a guard ring disposed in the vicinity of the display area DA.

In addition to the embodiments disclosed in FIGS. 8 to 17, the gate conductive pattern GCDP may have a variety of shapes and/or sizes. For example, the expanded pattern portion EXT of the gate conductive pattern GCDP may be formed in an appropriate size and/or shape depending on the space available around the active layer OACT. By forming the expanded pattern portion EXT, the gate conductive pattern GCDP can be more uniformly disposed in each pixel area PXA and the display area DA including it. For example, the expanded pattern portion EXT may include at least one of the first pattern EXT1, the second pattern EXT2, the third pattern EXT3, the fourth pattern EXT4 and the fifth pattern EXT5. The size or shape of the first pattern EXT1, the second pattern EXT2, the third pattern EXT3, the fourth pattern EXT4, and/or the fifth pattern EXT5 may be changed. According to an embodiment of the disclosure, the expanded pattern portion EXT may further include an additional pattern that may extend from at least one of the first pattern EXT1, the second pattern EXT2, the third pattern EXT3, the fourth pattern EXT4 and the fifth pattern EXT5 or may be disposed around at least one of the first pattern EXT1, the second pattern EXT2, the third pattern EXT3, the fourth pattern EXT4 and the fifth pattern EXT5. According to an embodiment of the disclosure, at least one dummy pattern may be provided in the same conductive layer as the gate conductive pattern GCDP and separated from the gate conductive pattern GCDP (e.g., the dummy pattern DMP in FIG. 17), a guard ring, and/or line, etc. may be disposed in the vicinity of the gate conductive pattern GCDP disposed on the active layer OACT of the first transistor OXT.

According to an embodiment of the disclosure, the gate conductive pattern GCDP may include a first metal layer MTL1 including titanium (Ti). Patterns provided in the same conductive layer as the gate conductive pattern GCDP may include a same material as the gate conductive pattern GCDP and may have substantially the same cross-sectional structure. For example, the patterns may include a first metal layer MTL1 containing titanium (Ti). According to an embodiment of the disclosure, the patterns of the conductive layer provided with the gate conductive pattern GCDP may further include a second metal layer MTL2 that may be disposed on the first metal layer MTL1 and may contain a metal with lower resistance than titanium (Ti).

According to an embodiment of the disclosure, the first metal layer MTL1 may be disposed on (e.g., directly on) an insulating layer (e.g., the fourth insulating layer 126) between the active layer ACT and the gate conductive pattern GCDP. According to an embodiment of the disclosure, the first metal layer MTL1 may have a thickness TH of about 300 Å or more.

According to the embodiments described above with reference to FIGS. 4 to 17, the gate electrode GE disposed on the active layer OACT of the first transistor OXT may be expanded such that it protrudes on both sides of the active layer OACT by a length equal to an extension length (e.g., predetermined or selectable extension length) EXL in the width direction of the active layer OACT. For example, the gate electrode GE of the first transistor OXT may protrude by about 4 μm or more on both sides of the active layer OACT in the width direction of the channel region CH overlapping the gate electrode GE. Accordingly, the channel region CH of the first transistor OXT can be stably covered by the gate electrode GE.

According to the above-described embodiments, the gate conductive pattern GCDP including the gate electrode GE may be further expanded in the vicinity of the active layer OACT. As an example, the gate conductive pattern GCDP may extend from the gate electrode GE and may include an expanded pattern portion EXT disposed in the vicinity of the active layer OACT. According to embodiments of the disclosure, the gate conductive pattern GCDP may include a material with high hydrogen adsorption capacity. For example, the gate conductive pattern GCDP may include a first metal layer MTL1 including titanium (Ti). According to an embodiment of the disclosure, the first metal layer MTL1 may have a thickness TH sufficient to improve hydrogen adsorption capacity. Accordingly, the amount of hydrogen (H) adsorbed by the gate conductive pattern GCDP can be increased, in order to prevent excessive introduction or diffusion of hydrogen (H) into the active layer OACT of the first transistor OXT. As a result, changes in the characteristics of the first transistor OXT can be prevented or reduced, and the characteristics of the first transistor OXT can become more uniform and/or can be stabilized. In this manner, it may be possible to improve the reliability of the first transistor OXT and the pixel PX including it.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
an active layer disposed on a substrate and comprising a first channel region, a first source region, and a first drain region;
an insulating layer disposed on the active layer; and
a gate conductive pattern disposed on the insulating layer,
wherein the gate conductive pattern comprises:
a first gate electrode overlapping a portion of the active layer corresponding to the first channel region, the first gate electrode protruding from opposing sides of the active layer by more than about 4 μm in a width direction of the first channel region; and
an expanded pattern portion extending from the first gate electrode and disposed in a vicinity of the active layer.

2. The display device of claim 1, wherein
the active layer comprises an oxide semiconductor, and
the gate conductive pattern comprises a first metal layer containing titanium (Ti).

3. The display device of claim 2, wherein the first metal layer has a thickness of about 300 Å or more.

4. The display device of claim 2, wherein the first metal layer is disposed directly on the insulating layer.

5. The display device of claim 2, wherein
the gate conductive pattern further comprises a second metal layer disposed on the first metal layer, and
the second metal layer contains a metal having a lower resistance than titanium (Ti).

6. The display device of claim 1, wherein
the expanded pattern portion comprises a first pattern disposed at a side of the first gate electrode in a first direction corresponding to the width direction of the first channel region, and
the expanded pattern portion extends in a second direction intersecting the first direction.

7. The display device of claim 6, wherein the second direction corresponds to a length direction of the first channel region.

8. The display device of claim 6, wherein the first pattern is disposed in parallel to at least a portion of the active layer in a plan view.

9. The display device of claim 6, wherein the expanded pattern portion further comprises a second pattern disposed at an opposite side of the first gate electrode in the first direction.

10. The display device of claim 9, wherein the second pattern extends in the second direction.

11. The display device of claim 6, wherein the active layer further comprises:
a second channel region spaced apart from the first channel region, the second channel region overlapping a portion of the gate conductive pattern, and
a second source region and a second drain region disposed at opposing sides of the second channel region, respectively.

12. The display device of claim 11, wherein the gate conductive pattern further comprises a second gate electrode overlapping the second channel region.

13. The display device of claim 12, wherein the second gate electrode protrudes from opposing sides of the active layer by more than about 4 μm in a width direction of the second channel region.

14. The display device of claim 12, wherein
the expanded pattern portion further comprises a third pattern extending from the second gate electrode,
the third pattern is spaced apart from the first pattern, and
the second gate electrode is disposed between the first pattern and the third pattern.

15. The display device of claim 14, wherein the third pattern is disposed in parallel to at least a portion of the active layer in a plan view.

16. The display device of claim 1, wherein the active layer and the expanded pattern portion do not overlap each other in a plan view.

17. The display device of claim 1, wherein the active layer and the expanded pattern portion overlap each other in a plan view.

18. The display device of claim 17, wherein
the active layer further comprises a dummy pattern portion,
the dummy pattern portion extends from the first source region or the first drain region,
the dummy pattern portion overlaps the expanded pattern portion, and
an end of the dummy pattern portion is electrically floating.

19. The display device of claim 1, further comprising:
a dummy pattern disposed on the insulating layer and separated from the gate conductive pattern, and
wherein the dummy pattern and the gate conductive pattern comprise a same material.

20. The display device of claim 1, further comprising:
a pixel comprising a transistor comprising the active layer and the first gate electrode.
